(19) United States
(12) Patent Application Publication
(10) Pub. No.: US 2010/0042353 A1
(43) Pub. Date: Feb. 18, 2010

(54) SYSTEM AND METHOD FOR TESTING WORKING CONDITION OF LED INDICATORS ON HARD DISK DRIVES

(75) Inventors: TAO HUANG, Shenzhen City (CN); HONG-BO ZHAO, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (CN)

(21) Appl. No.: 12/417,658

(22) Filed: Apr. 3, 2009

(30) Foreign Application Priority Data
Aug. 14, 2008 (CN) 200810303757.2

(51) Int. Cl. G01R 31/26; G06F 19/00

(52) U.S. Cl. 702/119; 324/767; 340/815.45

(57) ABSTRACT

A method is provided to test working condition of LED indicators on hard disk drives connected to a computer. The method calls an API function from an operating system of the computer to create a main thread, and creates a sub thread for each of the hard disk drives connected to the computer using the main thread. The method further activates an LED indicator on each of the hard disk drives by interchanging data between the hard disk drive and the computer according to the sub thread. In addition, the method determines whether the LED indicator is workable by checking a working state of the LED indicator on each of the hard disk drive drives, and generates a working condition report for the LED indicator on each of the hard disk drives by integrating the determination results.

### BACKGROUND

1. Technical Field

Embodiments of the present disclosure relate to systems and methods for testing working condition of light emitting diode (LED) indicators, and more particularly to a system and method for testing working condition of LED indicators on hard disk drives.

2. Related Art

A computer may include a hard disk drive having one or more LED indicators. The one or more LED indicators may be used as external signals, internal diagnostics, and for other suitable applications.

In order to verify whether the LED indicator contained in each of the hard disk drives works in a normal state, it is necessary to manually test working condition of the LED indicators on the hard disk drives. However, the increase in complexity and the decrease in accuracy of LED indicators on the hard disk drives may occur in the manual testing process. For example, if a human operator tests the working condition of LED indicators only by viewing the luminance of the LED indicators, the test would likely be inaccurate and error-prone because of man-made negligence in the manual testing process. More importantly, if multiple LED indicator on the hard disk drives need to be tested, the manual test requirements may become problematic and severely inefficient, resulting in a decrease in productivity.

Therefore, there is a improved system and method for a system and method for testing working condition of LED indicators on hard disk drives, which can increase accuracy and efficiency of testing the LED indicators on the hard disk drives.

### BRIEF DESCRIPTION OF THE DRAWINGS

FIG. 1 is a schematic diagram of one embodiment of a system for testing working condition of LED indicators on hard disk drives.

FIG. 2 is a schematic diagram illustrating function modules of the testing system of FIG. 1.

FIG. 3 is a flowchart of one embodiment of a method for testing working condition of LED indicators on hard disk drives by the testing system of FIG. 1.

### DETAILED DESCRIPTION

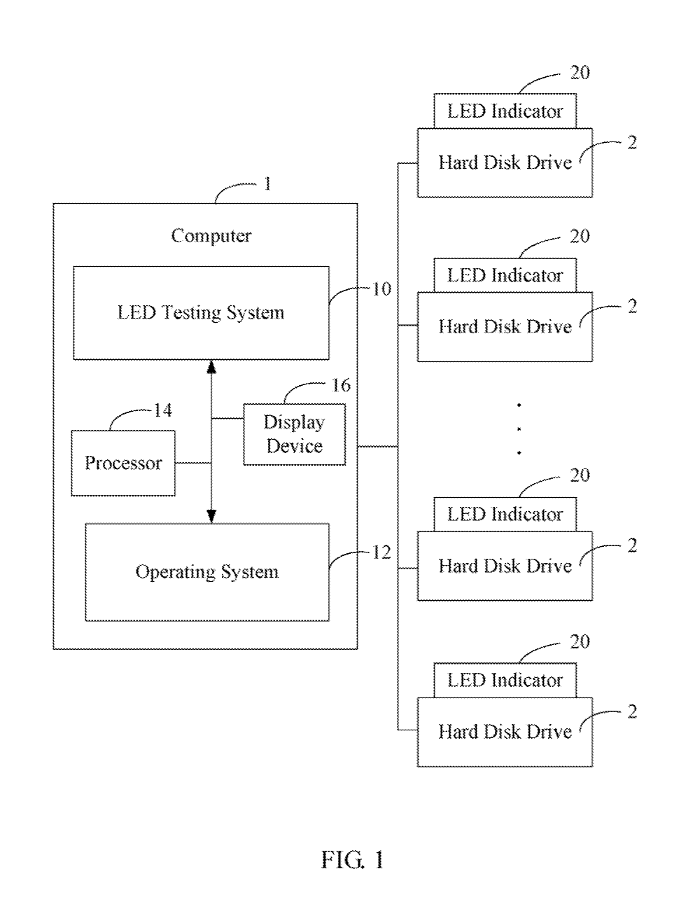

FIG. 1 is a schematic diagram of one embodiment of a system for testing working condition of LED indicators on hard disk drives (HDD). In one embodiment, the system for testing working condition of LED indicators on hard disk drives (hereinafter “LED testing system 10”) is implemented by a computer 1. The computer 1 is connected with one or more hard disk drives 2 via an input/output (I/O) port, which may be an RS-232 port, a universal serial bus (USB) port, or a network connection.

Each of the hard disk drives 2 includes an LED indictor 20, which is used to indicate whether the hard disk drive 2 interchanges data with the computer 1. For example, the LED indicator 20 of the hard disk drive 2 lights up when the hard disk drive 2 interchanges data with the computer 1, and the LED indicator 20 of the hard disk drive 2 does not light up when the hard disk drive 2 does not interchange data with the computer 1. In the embodiment, each of the hard disk drives 2 may be a formatted disk that may be stored with a plurality of test data, or an unformatted disk that has no test data. The test data can be any data that are used to interchange data between the hard disk drive 2 and the computer 1.

The computer 1 may include an operating system 12, at least one processor 14, and a display device 16. The operating system 12 provides a plurality of application programming interface (API) functions in communication with the testing system 10. The processor 14 is used to execute the testing system 10 to test working condition of the LED indictor 20 on each of the hard disk drives 2. The display device 16 is used to display a working condition report generated by the testing system 10.

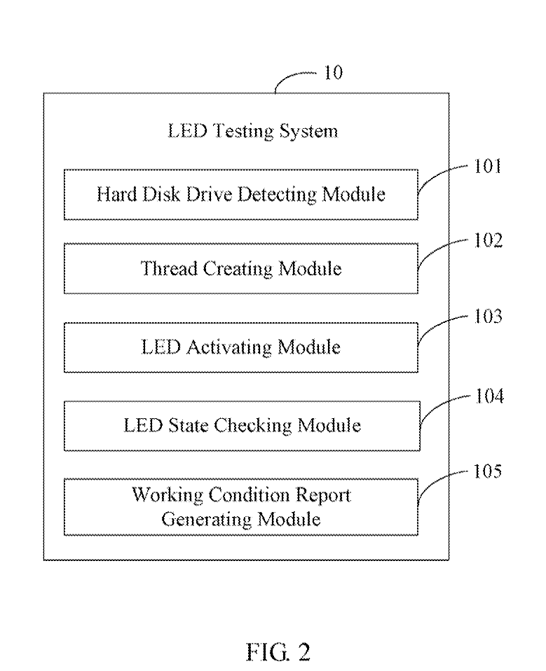

FIG. 2 is a schematic diagram illustrating function modules of the testing system 10 of FIG. 1. The test system 10 is configured for testing working condition of the LED indicator 20 contained in each of the hard disk drives 2 that are connected to the computer 1 simultaneously. In one embodiment, the testing system 10 may include a hard disk drive detecting module 101, a thread creating module 102, an LED activating module 103, an LED state checking module 104, and a working condition report generating module 105. Each of the function modules 101-104 can be executed by the at least one processor 14 of the computer 1.

The hard disk drive detecting module 101 is configured for detecting whether each of the hard disk drives 2 is connected to the computer 1, and obtaining the total number of the hard disk drives 2 connected to the computer 1. In one embodiment, if fifty hard disk drives 2 are successfully connected to the computer at same time, then the total number of hard disk drives 2 obtained by the hard disk drive detecting module 101 is fifty.

The thread creating module 102 is configured for creating a main thread by calling a first API function (e.g. a CreateThread function) from the operating system 12 of the computer 1, and creating a sub thread for each of the hard disk drives 2 connected to the computer 1 using the main thread. Each of the sub threads is used to interchange data between the corresponding hard disk drive 2 with the computer 1. For example, if the fifty hard disk drives 2 are connected to the computer 1, the thread creating module 102 creates fifty sub threads for the fifty hard disk drives using the main thread. In one embodiment, the thread creating module 102 creates the main thread using a pseudo code as follows: HANDLE hMainThread=CreateThread(NULL, 0, MainThreadProc, (LPVOID)this, CREATE_SUSPENDED, &dwThreadID), wherein the parameter of “MainThreadProc” defines a main thread function for creating the main thread. When a sub thread for each of the hard disk drives 2 needs to be created, the thread creating module 102 creates a sub thread by modifying the parameter of “MainThreadProc” in the pseudo code.

The LED activating module 103 is configured for activating the LED indicator 20 on each of the hard disk drives 2 by interchanging data between the hard disk drive 2 and the computer 1 based on the sub thread corresponding to the hard disk drive 2. In one embodiment, one sub thread designates a sector of the corresponding hard disk drive 2 by calling a second API function (e.g., a SetFilePointer function) from the operating system 12 of the computer 1, and reads the test data of the corresponding hard disk drive 2 to activate the LED indicator 20. When the sub thread reads the test data of the hard disk drive 2, the LED indicator 20 on the hard disk drive 2 lights up if the hard disk drive 2 interchanges data with the computer 1. Otherwise, if the hard disk drive 2 does not interchange data with the computer 1, the LED indicator 20 on the hard disk drive 2 does not light up.

The LED state checking module 104 is configured for checking a working state of the LED indicator 20 on each of the hard disk drives 2, and determining whether the LED indicator 20 is workable according the working state of the LED indicator 20. In one embodiment, if the LED indicator 20 on the hard disk drive 2 is in a brightness state (e.g., the LED indicator 20 lights up), the LED state checking module 104 determines that the LED indicator 20 works normally. If the LED indicator 20 of the hard disk drive 2 is in a darkness state (e.g., the LED indicator 20 does not light up), the LED state checking module 104 determines that the LED indicator 20 does not work normally.

The working condition report generating module 105 is configured for generating a working condition report of the LED indicators 20 on the hard disk drives 2 by integrating all of the determination results, and displaying the working condition report on the display device 16 of the computer 1. As such, a test engineer can evaluate working condition of the LED indicators 20 on the hard disk drives 2 according to the working condition report.

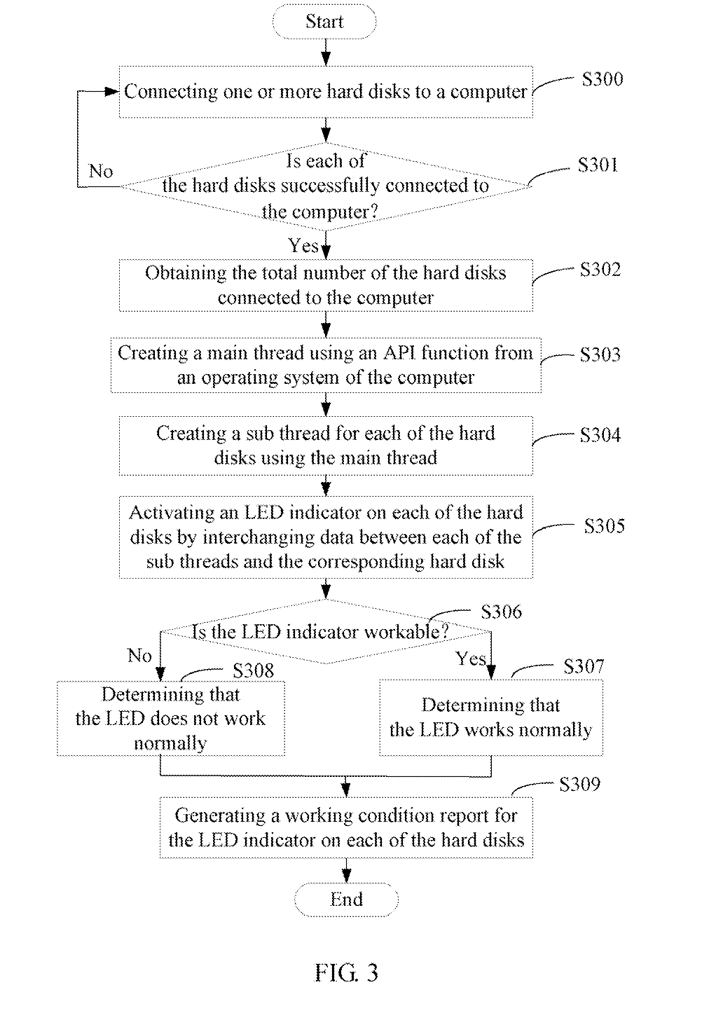

FIG. 3 is a flowchart of one embodiment of a method for testing working condition of LED indicators on hard disk drives by the testing system 10 of FIG. 1 as described above. Depending on the embodiment, additional blocks may be added, others removed, and the ordering of the blocks may be changed.

In block S300, a test engineer connects one or more hard disk drives 2 to the computer 1 via the I/O port. When the one or more hard disk drives 2 connects to the computer 1, the processor 14 initializes the hard disk drive detecting module 101, the thread creating module 102, the LED activating module 103, the LED state checking module 104, and the working condition report generating module 105 of the testing system 10 to test the LED indicators 20 on the one or more hard disk drives 2.

In block S301, the hard disk drive detecting module 101 detects whether each of the hard disk drives 2 is successfully connected to the computer 1. If each of the hard disk drives 2 is successfully connected to the computer 1, the procedure goes to block S302 as described below. Otherwise, if one of the hard disk drives 2 is unsuccessfully connected to computer 1, the procedure returns to block S300 as described above.

In block S302, the hard disk drive detecting module 101 obtains the number of the hard disk drives 2 connected to the computer 1. As mentioned above, when fifty hard disk drives are successfully connected to the computer 1, then fifty numbers hard disk drives are obtained by the hard disk drive detecting module 101.

In block S303, the thread creating module 102 calls an API function (e.g. CreateThread function) from the operating system 12 of the computer 1 to create a main thread. As mentioned above, the thread creating module 102 creates the main thread by using a pseudo code as follows: HANDLE hMainThread=CreateThread(NULL, 0, MainThreadProc, (LPVOID)this, CREATE_SUSPENDED, &dwThreadID), wherein the parameter of “MainThreadProc” defines a main thread function for creating the main thread.

In block S304, the thread creating module 102 creates a sub thread for each of the hard disk drives 2 being connected to the computer 1 by using the main thread. In one embodiment, the thread creating module 102 modifies the parameter of “MainThreadProc” in the pseudo code so as to create the sub thread for each of the hard disk drives 2. Each of the sub threads interchanges data between the corresponding hard disk drive 2 and the computer 1 when the sub thread is created.

In block S305, when one of the hard disk drives 2 interchanges data with the computer 1 based on the sub thread corresponding to the hard disk drive 2, then the LED activating module 103 activates the LED indicator 20 of the hard disk drive 2. When the sub thread reads the test data of the hard disk drive 2, the LED indicator 20 of the hard disk drive 2 lights up if the hard disk drive 2 interchanges data with the computer 1. Otherwise, if the hard disk drive 2 does not interchange data with the computer 1, the LED indicator 20 of the hard disk drive 2 does not light up.

In block S306, the LED state checking module 104 determines whether the LED indicator 20 does work normally by checking the working state of the LED indicator 20 on each of the hard disk drives 2. If the LED indicator 20 of the hard disk drive 2 is in a brightness state, in block S307, the LED state checking module 104 determines that the LED indicator 20 works normally. Otherwise, if the LED indicator 20 of the hard disk drive 2 is in a darkness state, in block S308, the LED state checking module 104 determines that the LED indicator 20 does not work normally.

In block S309, the working condition report generating module 105 generates a working condition report on the LED indicators 20 of the hard disk drives 2 by integrating all of the determination results. In one embodiment, the working condition report generating module 105 displays the working condition report on the display device 16 of the computer 1. In another embodiment, the working condition report generating module 105 may store the working condition report in a storage device of the computer 1. As such, a test engineer can evaluate working condition of the LED indicators 20 on the hard disk drives 2 according to the working condition report.

All of the processes described above may be embodied in, and fully automated via, functional code modules executed by one or more general purpose computers or processors. The functional code modules may be stored in any type of computer-readable medium or other computer storage device. Some or all of the methods may alternatively be embodied in specialized computer hardware.

Although certain inventive embodiments of the present disclosure have been specifically described, the present disclosure is not to be construed as being limited thereto. Various changes or modifications may be made to the present disclosure without departing from the scope and spirit of the present disclosure.

What is claimed is:

1. A system for testing working condition of LED indicators on hard disk drives, the system being implemented by a computer connected with one or more hard disk drives, the system comprising:
a thread creating module configured for creating a main thread using an application programming interface (API) function from an operating system of the computer, and creating a sub thread for each of the one or more hard disk drives connected to the computer using the main thread;
an LED activating module configured for activating an LED indicator on each of the one or more hard disk drives by interchanging data between the hard disk drive and the computer according to each of the sub threads corresponding to each of the one or more hard drives;
an LED state checking module configured for checking a working state of the LED indicator on each of the one or more hard disk drives, and determining whether the LED indicator on each of the one or more hard disk drives is workable according to the working state of the LED indicator; and
a working condition report generating module configured for generating a working condition report for the LED indicator on each of the one or more hard disk drives by integrating the determination results, and displaying the working condition report on a display device of the computer.

2. The system according to claim 1, wherein the working state of the LED indicator on each of the one or more hard disk drives is in a brightness state if the hard disk drive interchanges data with the computer, and in a darkness sate if the hard disk drive does not interchange data with the computer.

3. The system according to claim 1, wherein the LED state checking module determines that the LED indicator works normally when the LED indicator lights up, and determines that the LED indicator does not work normally when the LED indicator does not light up.

4. The system according to claim 1, further comprising a hard disk drive detecting module configured for detecting whether each of the one or more hard disk drives is connected to the computer successfully, and obtaining the total number of the hard disk drives connected to the computer.

5. The system according to claim 1, wherein the one or more hard disk drives are connected to the computer via an I/O port, which is selected from the group consisting of an RS-232 port, an USB port, and a network connection.

6. The system according to claim 1, wherein each of the one or more hard disk drives is a formatted disk or an unformatted disk.

7. A computer-enabled method for testing working condition of LED indicators on hard disk drives, the method comprising:
connecting one or more hard disk drives to a computer via an I/O port;
creating a main thread by calling an application programming interface (API) function from an operating system of the computer;
creating a sub thread for each of the one or more hard disk drives connected to the computer using the main thread;
activating an LED indicator on each of the one or more hard disk drives by interchanging data between the hard disk drive and the computer according to each of the sub threads corresponding to the each of the one or more hard disk drives;
determining whether the LED indicator is workable by checking a working state of the LED indicator on each of the one or more hard disk drives;
generating a working condition report for the LED indicator on each of one or more the hard disk drives by integrating the determination results; and
displaying the working condition report on a display device of the computer.

8. The method according to claim 7, further comprises:
detecting whether each of the hard disk drives is successfully connected to the computer;
connecting the hard disk drive to the computer via the I/O port if one of the hard disk drives is unsuccessfully connected to computer; and
obtaining the total number of the hard disk drives connected to the computer if each of the hard disk drives is successfully connected to the computer.

9. The method according to claim 7, wherein the working state of the LED indicator on each of the hard disk drives is in a brightness state if the hard disk drive interchanges data with the computer, and in a darkness state if the hard disk drive does not interchange data with the computer.

10. The method according to claim 7, further comprising:
determining that the LED indicator does work normally if the LED indicator lights up; and
determining that the LED indicator does not work normally if the LED indicator does not light up.

11. The method according to claim 7, wherein the API function is a CreateThread function that is used to create the main thread and the sub thread.

12. The method according to claim 7, wherein the I/O port is selected from the group consisting of an RS-232 port, an USB port, and a network connection.

13. The method according to claim 7, wherein each of the one or more hard disk drives is a formatted disk or an unformatted disk.

14. A computer-readable medium having stored thereon instructions that, when executed by a processor of a computer, cause the computer to perform a method for testing working condition of LED indicators on hard disk drives, the method comprising:
connecting the hard disk drives to a computer via an I/O port;
creating a main thread by calling an application programming interface (API) function from an operating system of the computer;
creating a sub thread for each of the hard disk drives connected to the computer using the main thread;
activating an LED indicator on each of the hard disk drives by interchanging data between the hard disk drive and the computer according to each of the sub threads corresponding to each of the hard disk drives;
determining whether the LED indicator is workable by checking a working state of the LED indicator on each of the hard disk drives;
generating a working condition report for the LED indicator on each of the hard disk drives by integrating the determination results; and
displaying the working condition report on a display device of the computer.

15. The medium according to claim 14, wherein the method further comprises:
detecting whether each of the hard disk drives is successfully connected to the computer;
connecting the hard disk drive to the computer via the I/O port if one of the hard disk drives is unsuccessfully connected to computer; and
obtaining the total number of the hard disk drives connected to the computer if each of the hard disk drives is successfully connected to the computer.

16. The medium according to claim 14, wherein the working state of the LED indicator on each of the hard disk drives is in a brightness state if the hard disk drive interchanges data with the computer, and in a darkness state if the hard disk drive does not interchange data with the computer.

17. The medium according to claim 14, wherein the method further comprises:
determining that the LED indicator does work normally if the LED indicator lights up; and
determining that the LED indicator does not work normally if the LED indicator does not light up.

18. The medium according to claim 14, wherein the API function is a CreateThread function that is used to create the main thread and the sub thread.

19. The medium according to claim 14, wherein each of the hard disk drives is a formatted disk or an unformatted disk.
